(19) United States
(12) Patent Application Publication
(10) Pub. No.: US 2023/0371349 A1
(43) Pub. Date: Nov. 16, 2023

(54) DISPLAY DEVICE AND MANUFACTURING METHOD THEREOF

(71) Applicant: Samsung Display Co., Ltd., Yongin-si (KR)

(72) Inventors: Soo Dong KIM, Yongin-si (KR); YOUNGSOO KWON, Yongin-si (KR)

(21) Appl. No.: 18/189,048

(22) Filed: Mar. 23, 2023

(30) Foreign Application Priority Data
May 16, 2022 (KR) 10-2022-0059422

(51) Int. Cl. H10K 59/80; H10K 59/12; H10K 59/38

(52) U.S. Cl. CPC H10K 59/8792; H10K 59/1201; H10K 59/38

(57) ABSTRACT

Provided is a manufacturing method of a display device including forming banks having a plurality of openings between the banks on a substrate, injecting a color conversion layer inkjet composition including non-reactive monomers into the openings between the banks, forming a color conversion layer by curing the color conversion layer inkjet composition, and volatilizing the non-reactive monomers by applying heat to the color conversion layer.

### CROSS-REFERENCE TO RELATED APPLICATION

This application claims priority to and the benefit of Korean Patent Application No. 10-2022-0059422 filed in the Korean Intellectual Property Office on May 16, 2022, the entire contents of which are hereby incorporated by reference.

### BACKGROUND

### 1. Field

Embodiments of the present disclosure relate to a display device and a manufacturing method thereof, and, for example, to a display device having high light efficiency and a manufacturing method thereof.

### 2. Description of the Related Art

A display device, such as a light emitting diode display, realizes an image by generating light based on the principle that holes and electrons injected from an anode and a cathode are recoupled in a light emitting layer to emit light. The display device includes pixels that emit light of any one color of, for example, red, green, and blue to express a desired color by a combination of these colors.

To this end, each pixel includes a light emitting diode that generates monochromatic light such as white or blue, and a quantum dot layer, a color filter, and the like to convert the monochromatic light into a desired color of red, green, or blue to emit the light. That is, when the light emitting diode of each pixel generates the monochromatic light, the monochromatic light is converted into one of red, green, or blue colors while passing through the quantum dot layer and the color filter and then emitted, and an image of a desired color may be realized by a color combination of the pixels emitted with the appropriate color.

The quantum dot layer may be formed by an inkjet method.

The above information disclosed in this Background section is only for enhancement of understanding of the background of the present disclosure, and therefore it may contain information that does not form the prior art that is already known in this country to a person of ordinary skill in the art.

### SUMMARY

The subject matter of the present disclosure has been made in an effort to provide a display device having improved light emission efficiency.

An example embodiment of the present disclosure provides a manufacturing method of a display device including forming banks having a plurality of openings between the banks on a substrate, injecting a color conversion layer inkjet composition including non-reactive monomers into the openings between the banks, forming a color conversion layer by curing the color conversion layer inkjet composition, and volatilizing the non-reactive monomers by applying heat to the color conversion layer.

The color conversion layer inkjet composition may include quantum dots, scatterers, and reactive monomers.

In the forming of the color conversion layer by curing the color conversion layer inkjet composition, the reactive monomers may react.

The reactive monomer may include hexamethylene diacrylate.

The non-reactive monomer may have a structure in which diacrylate is removed from the hexamethylene diacrylate.

In the color conversion layer inkjet composition, the sum of the contents of the quantum dots and the scatterers may be 60 wt % or less.

The content of the non-reactive monomers may be 0.1 wt % to 95 wt % of the content of the reactive monomers.

The color conversion layer inkjet composition may further include one or more curing agents selected from the group consisting of compounds represented by Chemical Formulas 3 to 6 below.

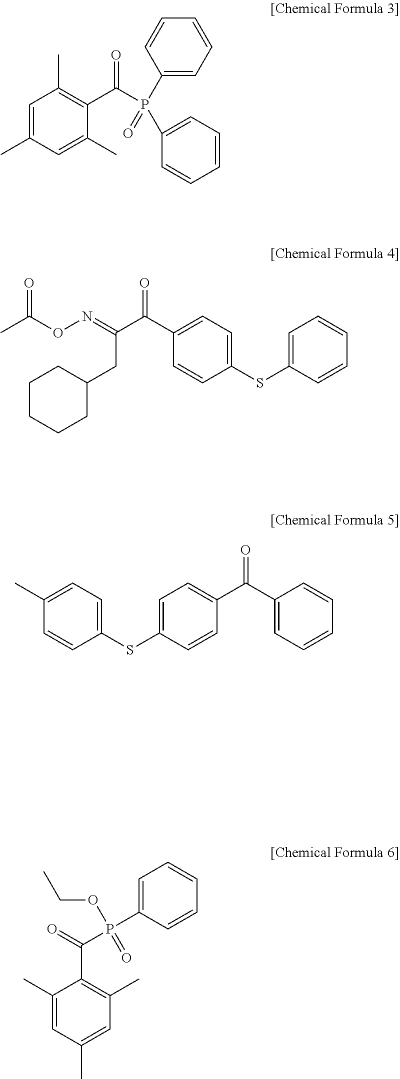 [SMILES: Cc1cc(C)c(C(=O)P(=O)(c2ccccc2)c2ccccc2)c(C)c1 ; CC(=O)O/N=C(\CC1CCCCC1)C(=O)c1ccc(Sc2ccccc2)cc1 ; Cc1ccc(Sc2ccc(C(=O)c3ccccc3)cc2)cc1 ; CCOP(=O)(C(=O)c1c(C)cc(C)cc1C)c1ccccc1]

The content of the curing agent may be 0.1 wt % to 10 wt % in the color conversion layer inkjet composition.

The color conversion layer inkjet composition may further include one or more dispersing agents selected from the group consisting of compounds of Chemical Formulas 7 to 9 below.

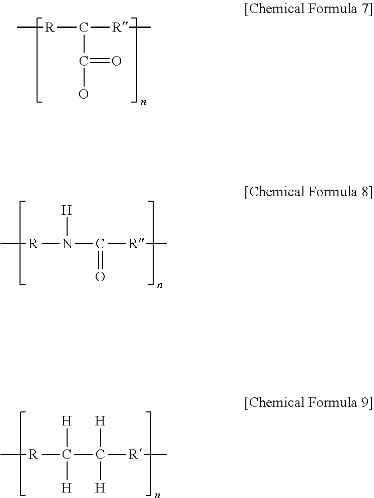

In Chemical Formulas 7 to 9, R and R′ may be amines or amine acids.

The content of the dispersing agent may be 0.1 wt % to 10 wt % in the color conversion layer inkjet composition.

The vapor pressure of the color conversion layer inkjet composition may be 10⁻⁶ mmHg to 10⁻¹ mmHg.

The surface energy of the color conversion layer inkjet composition may be 1 dyne/cm to 40 dyne/cm.

The viscosity of the color conversion layer inkjet composition may be 1 cps to 40 cps.

In the volatilizing of the non-reactive monomers by applying the heat to the color conversion layer, the thickness of the color conversion layer may be reduced.

The manufacturing method of the display device may further include removing a portion of the banks protruding above the color conversion layer, after the volatilizing of the non-reactive monomers by applying the heat to the color conversion layer.

The density of the quantum dots of the color conversion layer after the volatilizing of the non-reactive monomers by applying the heat to the color conversion layer may be higher than the density of the quantum dots of the color conversion layer after the forming of the color conversion layer by curing the color conversion layer inkjet composition.

Another example embodiment of the present disclosure provides a display device including a color conversion panel, and a display panel positioned to overlap with the color conversion panel, in which the display panel may include a first substrate, a plurality of barriers positioned on the first substrate, and a light emitting layer positioned between adjacent ones of the barriers, and the color conversion panel may include a second substrate, a bank positioned on the second substrate and partitioning a first light emitting area, a second light emitting area, and a third light emitting area, a bank positioned on the second substrate and partitioning a first light emitting area, a second light emitting area, and a third light emitting area, and an additional layer positioned on the color conversion layers, in which the additional layer may not overlap with the bank.

The height of the bank may be 1 um to 10 um.

The color conversion layer may include quantum dots, scatterers, and non-reactive monomers.

According to example embodiments, it is possible to provide a display device with improved light emission efficiency.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a diagram schematically illustrating a cross section of a display device according to an example embodiment.

FIGS. 2 to 5 are cross-sectional views illustrating a manufacturing process of a red color conversion layer FIG. 1, which illustrate a portion indicated by B in the display device of FIG. 1.

FIG. 6 is a graph showing a comparison of light emission efficiencies in Example 1 in which a volatilization process of non-reactive monomers is included and Example 2 in which the volatilization process of the non-reactive monomer is not included.

FIG. 7 is a graph showing a comparison of efficiencies before and after volatilization of the non-reactive monomers while varying the thickness of a color conversion layer.

FIG. 8 is a graph showing a comparison of efficiencies before and after volatilization of the non-reactive monomers while varying the thickness of a color conversion layer.

FIG. 9 is a surface image of a Comparative Example in which non-reactive monomers are volatilized after inkjet jetting.

FIG. 10 is a surface image of a Comparative Example in which non-reactive monomers are volatilized in a curing process.

FIG. 11 is a surface image of an Example in which non-reactive monomers are volatilized after curing according to embodiments of the present disclosure.

FIG. 12 illustrates Experimental Example 1 showing efficiency after volatilizing non-reactive monomers and removing a bank in a state where the contents of quantum dots and scatterers are not reduced, and Experimental Example 2 showing efficiency after volatilizing non-reactive monomers and removing a bank in a state where the respective contents of quantum dots and scatterers are reduced.

FIGS. 13 and 14 illustrate Example in which an additional layer is formed after volatilizing non-reactive monomers.

FIG. 15 is an image shown by measuring the density of quantum dots.

FIG. 16 illustrates a display device according to an example embodiment.

FIGS. 17 to 19 illustrate a stacking order of a blue color filter, a red color filter, and a green color filter.

### DETAILED DESCRIPTION

The subject matter of the present disclosure will be described more fully hereinafter with reference to the accompanying drawings, in which various example embodiments of the present disclosure are shown. The subject matter of the present disclosure may be implemented in various suitable different forms and is not limited to the example embodiments described herein.

A part irrelevant to the description may be omitted to clearly describe the subject matter of the present disclosure, and the same elements will be designated by the same reference numerals throughout the specification.

In addition, each configuration illustrated in the drawings may be arbitrarily shown for understanding and ease of description, but the present disclosure is not limited thereto. In the drawings, the thickness of layers, films, panels, regions, etc., may be exaggerated for clarity. In addition, in the drawings, for convenience of description, thicknesses of a part and an area may be exaggeratedly illustrated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, when an element is referred to as “on” a reference portion the element may be positioned above or below the reference portion and is not particularly limited to being “above” or “on” the direction opposite to gravity.

In addition, unless explicitly described to the contrary, the word “comprise”, and variations such as “comprises” or “comprising”, will be understood to imply the inclusion of stated elements but not the exclusion of any other elements.

In addition, throughout the specification, “on a plane” means viewing a target part from the top and “on a cross section” means viewing a cross section acquired by vertically cutting the target part from the side.

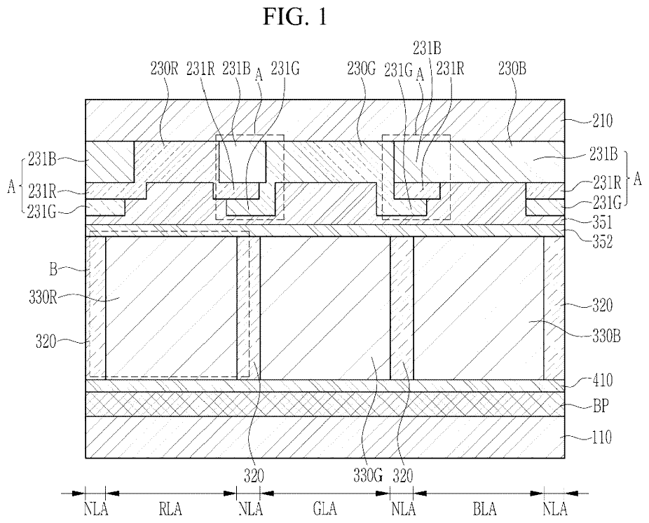

Hereinafter, a display device according to an example embodiment and a manufacturing method thereof will be described in more detail with reference to the drawings. FIG. 1 is a diagram schematically illustrating a cross section of a display device according to an example embodiment. Referring to FIG. 1, the display device according to the example embodiment includes an organic light emitting diode layer BP and color conversion layers 330R and 330G. Accordingly, light emitted from the organic light emitting diode layer BP is color-converted through the color conversion layers 330R and 330G to be emitted.

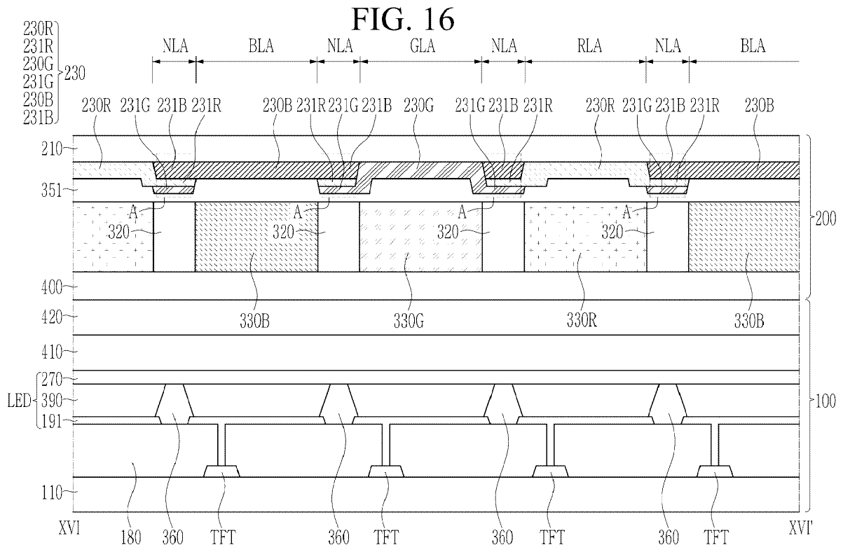

Referring to FIG. 1, the organic light emitting diode layer BP is positioned on a first substrate 110. The organic light emitting diode layer BP may include a plurality of transistors and a light emitting diode connected thereto to emit the light. In some embodiments, the transistor may include a semiconductor layer, a source electrode and a drain electrode connected to the semiconductor layer, and a gate electrode insulated from the semiconductor layer. The light emitting diode may include a first electrode, a light emitting layer, and a second electrode, which are connected to the transistor. Each light emitting diode may emit light having a different color and may also emit light having the same color. An example structure of the organic light emitting diode layer BP will be further described below with reference to FIG. 16.

In FIG. 1, an encapsulation layer 410 may be positioned on the organic light emitting diode layer BP. The encapsulation layer 410 may have a multi-layered structure in which organic layers and inorganic layers are alternately stacked. In the multi-layered encapsulation layer 410, a layer positioned farthest from the first substrate 110 may include SiON.

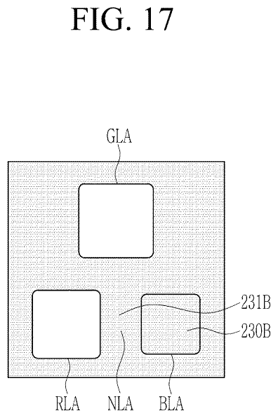

A color filter 230 (shown in FIG. 16) including a blue color filter 230B, a red color filter 230R, and a green color filter 230G may be positioned on a surface of a second substrate 210 facing the first substrate 110. Referring to FIG. 1, a blue dummy color filter 231B is positioned on the same layer as the blue color filter 230B. An area in which the blue color filter 230B is positioned becomes a blue light emitting area BLA. Although the blue color filter 230B and the blue dummy color filter 231B are illustrated as separate components in FIG. 1, the blue color filter 230B and the blue dummy color filter 231B may actually be connected to each other. An example form will be described in more detail below with reference to FIGS. 17 to 19.

Next, the red color filter 230R and a red dummy color filter 231R are positioned on the blue color filter 230B and the blue dummy color filter 231B. An area in which the red color filter 230R is positioned becomes a red light emitting area RLA.

Next, the green color filter 230G and a green dummy color filter 231G are positioned on the blue color filter 230B, the blue dummy color filter 231B, the red color filter 230R, and the red dummy color filter 231R. An area in which the green color filter 230G is positioned becomes a green light emitting area GLA.

Referring to FIG. 1, the blue dummy color filter 231B, the red dummy color filter 231R, and the green dummy color filter 231G are positioned to overlap with each other in an area overlapping with a bank 320. The blue dummy color filter 231B, the red dummy color filter 231R, and the green dummy color filter 231G overlap with each other to form a color filter overlapping body A. Such a color filter overlapping body A may function in the same manner as a light blocking member. For example, the color filter overlapping body A may block (or reduce transmission of) light in a non-light emitting area NLA.

Referring to FIG. 1, a low refractive index layer 351 may be positioned on the color filter 230. The low refractive index layer 351 may have a refractive index of 1.2 or less. The low refractive index layer 351 may include a mixture of an organic material and an inorganic material.

A support layer 352 may be positioned on the low refractive index layer 351. The support layer 352 may be an inorganic layer. A plurality of banks 320 are positioned on the support layer 352. The banks 320 may be spaced apart from each other with a plurality of openings therebetween, and each opening may overlap with each of the color filters 230R, 230G, and 230B in a direction vertical to the surface of the second substrate 210.

The bank 320 may include scatterers (e.g., light scatterers). The scatterers may be one or more selected from the group consisting of SiO₂, BaSO₄, Al₂O₃, ZnO, ZrO₂ and TiO₂. The bank 320 may include a polymer resin and scatterers included in the polymer resin. The content of the scatterers may be 0.1 wt % to 20 wt % (e.g., based on 100 wt % of the bank 320). For example, the content of the scatterers may be 5 wt % to 10 wt %. The bank 320 including the scatterers in this range scatters the light emitted from the display panel to increase light emission efficiency. In another example embodiment, the bank 320 may include a black material to block (or reduce transmission of) light and also prevent or reduce color mixing between neighboring light emitting areas.

A red color conversion layer 330R, a green color conversion layer 330G, and a transmission layer 330B are positioned in an area between the banks 320 spaced apart from each other. In FIG. 1, the red color conversion layer 330R is positioned in an area overlapping with the red emission area RLA. The red color conversion layer 330R may convert the supplied light to red. The red color conversion layer 330R may include quantum dots. The green color conversion layer 330G may convert the supplied light to green. The green color conversion layer 330G may include quantum dots.

The quantum dots will be described in more detail below.

In the present specification, the quantum dots (hereinafter, also referred to as semiconductor nanocrystals) may include Group II-VI compounds, Group III-V compounds, Group IV-VI compounds, Group IV elements or compounds, Group I-III-VI compounds, Group II-Ill-VI compounds, Group I-II-IV-VI compounds, or combinations thereof.

The Group II-VI compounds may be selected from the group consisting of binary compounds selected from the group consisting of CdSe, CdTe, ZnS, ZnSe, ZnTe, ZnO, HgS, HgSe, HgTe, MgSe, MgS and a mixture thereof; ternary compounds selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof. The Group II-VI compounds may also further include Group III metals.

The Group III-V compounds may be selected from the group consisting of binary compounds selected from the group consisting of GaN, GaP, GaAs, GaSb, AlN, AIP, AIAs, AlSb, InN, InP, InAs, InSb and a mixture thereof; ternary compounds selected from the group consisting of GaNP, GaNAs, GaNSb, GaPAs, GaPSb, AINP, AINAs, AINSb, AIPAs, AIPSb, InGaP, InNP, InNAs, InNSb, InPAs, InZnP, InPSb and a mixture thereof; and quaternary compounds selected from the group consisting of GaAINP, GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb, InZnP, and a mixture thereof. The Group III-V compounds may also further include Group II metals (e.g., InZnP).

The Group IV-VI compounds may be selected from the group consisting of binary compounds selected from the group consisting of SnS, SnSe, SnTe, PbS, PbSe, PbTe and a mixture thereof; ternary compounds selected from the group consisting of SnSeS, SnSeTe, SnSTe, PbSeS, PbSeTe, PbSTe, SnPbS, SnPbSe, SnPbTe and a mixture thereof; and quaternary compounds selected from the group consisting of SnPbSSe, SnPbSeTe, SnPbSTe and a mixture thereof.

The Group IV elements or compounds may be selected from the group consisting of elementary compounds selected from the group consisting of Si, Ge, and a combination thereof; and binary compounds selected from the group consisting of SiC, SiGe and a combination thereof, but are not limited thereto.

Examples of the Group I-III-VI compounds include CuInSe₂, CuInS₂, CuInGaSe and CuInGaS, but are not limited thereto. Examples of the Group I-II-IV-VI compounds include CuZnSnSe and CuZnSnS but are not limited thereto. The Group IV elements or compounds may be selected from the group consisting of elementary compounds selected from the group consisting of Si, Ge, and a combination thereof; and binary compounds selected from the group consisting of SiC, SiGe and a combination thereof.

The Group II-Ill-VI compounds may be selected from the group consisting of ZnGaS, ZnAlS, ZnInS, ZnGaSe, ZnAlSe, ZnlnSe, ZnGaTe, ZnAlTe, ZnlnTe, ZnGaO, ZnAlO, ZnlnO, HgGaS, HgAIS, HgInS, HgGaSe, HgAlSe, HglnSe, HgGaTe, HgAlTe, HglnTe, MgGaS, MgAIS, MgInS, MgGaSe, MgAlSe, MglnSe and combinations thereof, but are not limited thereto.

The Group I-II-IV-VI compounds may be selected from CuZnSnSe and CuZnSnS but are not limited thereto.

In an example embodiment, the quantum dots may not include cadmium.

The quantum dots may include semiconductor nanocrystals based on the Group III-V compounds including indium and phosphorus. The Group III-V compounds may further include zinc. The quantum dots may include semiconductor nanocrystals based on the Group II-VI compounds including a chalcogen element (e.g., sulfur, selenium, tellurium, or combinations thereof) and zinc.

In the quantum dots, the above-mentioned binary compounds, ternary element compounds, and/or quaternary compounds may be present in particles at a uniform (e.g., substantially uniform) concentration or may be present in the same particles in which the concentration distribution is partially divided into different states. In addition, the quantum dots may have a core/shell structure in which one quantum dot surrounds another quantum dot or other quantum dots. An interface between the core and the shell may have a concentration gradient in which the concentration of the elements in the shell decreases along a direction toward the center.

In some example embodiments, quantum dots may have a core-shell structure including a core including the aforementioned nanocrystals and a shell surrounding the core. The shell of the quantum dot may serve as a protective layer for maintaining semiconductor properties and/or as a charging layer for imparting electrophoretic properties to the quantum dot by preventing or reducing chemical modification of the core. The shell may be a single layer or multi-layer. The interface between the core and the shell may have a concentration gradient in which the concentration of the elements in the shell decreases along a direction toward the center. Examples of the shell of the quantum dot may include a metal and/or non-metal oxide, a semiconductor compound, a combination thereof, and/or the like.

For example, examples of the metal and/or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO, and/or the like, and/or a ternary compound such as MgAl₂O₄, CoFe₂O₄, NiFe₂O₄, CoMn₂O₄, and/or the like, but is not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AIP, AISb, and the like, but the present disclosure is not limited thereto.

An interface between the core and the shell may have a concentration gradient in which the concentration of the elements in the shell decreases along a direction toward the center. In addition, the semiconductor nanocrystal may also have a structure including one semiconductor nanocrystal core and a multi-layered shell surrounding the semiconductor nanocrystal core. In one example embodiment, the multi-layered shell may have two or more layers, e.g., 2, 3, 4, 5, or more layers. The two adjacent layers of the shell may have a single composition or different compositions. In the multi-layered shell, each layer may have a composition that varies according to a radius.

The quantum dots may have a full width of half maximum (FWHM) of the emission wavelength spectrum of about 45 nm or less, about 40 nm or less, or, for example, about 30 nm or less, and color purity and/or color reproducibility may be improved in this range. In addition, because light emitted through the quantum dots is emitted in all (or substantially all) directions, a wide viewing angle may be improved.

In the quantum dots, a shell material and a core material may have different energy bandgaps. For example, the energy bandgap of the shell material may be larger than that of the core material. In another example, the energy bandgap of the shell material may be smaller than that of the core material. The quantum dot may have a multi-layered shell. In the multi-layered shell, the energy bandgap of an outer layer may be larger than the energy bandgap of an inner layer (e.g., a layer closer to the core). In the multi-layered shell, the energy bandgap of the outer layer may also be smaller than the energy bandgap of the inner layer.

The quantum dots may control the absorption/emission wavelengths by adjusting the composition and size thereof. The maximum emission peak wavelength of the quantum dot may have a wavelength range of ultraviolet to infrared wavelengths or more.

The quantum dots may have quantum efficiency of about 10% or more, for example, about 30% or more, about 50% or more, about 60% or more, about 70% or more, about 90% or more, or even 100%. The quantum dots may have a relatively narrow spectrum (e.g., the quantum dots may emit light in a relatively narrow wavelength range). The quantum dots may have, for example, a FWHM of the emission wavelength spectrum of about 50 nm or less, for example, about 45 nm or less, about 40 nm or less, or about 30 nm or less.

The quantum dots may have particle sizes of about 1 nm or more and about 100 nm or less. The particle size refers to a particle diameter or a diameter converted by assuming a spherical shape from a two-dimensional image obtained by transmission electron microscope analysis. The quantum dots may have sizes of about 1 nm to about 20 nm, for example, 2 nm or more, 3 nm or more, or 4 nm or more and 50 nm or less, 40 nm or less, 30 nm or less, 20 nm or less, 15 nm or less, or, for example, 10 nm or less. The shapes of the quantum dots are not particularly limited. For example, the shapes of the quantum dots may include a sphere, a polyhedron, a pyramid, a multipod, a square, a cuboid, a nanotube, a nanorod, a nanowire, a nanosheet, or a combination thereof, but are not limited thereto.

The quantum dots are commercially available or may be suitably or appropriately synthesized. The particle size of the quantum dot may be relatively freely controlled during colloidal synthesis, and the particle size may be uniformly (e.g., substantially uniformly) controlled.

The quantum dot may include an organic ligand (e.g., with a hydrophobic and/or hydrophilic moiety). The organic ligand moiety may be bound to the surface of the quantum dot. The organic ligand includes RCOOH, RNH₂, R₂NH, R₃N, RSH, R₃PO, R₃P, ROH, RCOOR, RPO (OH)₂, RHPOOH, RHPOOH, or a combination thereof, wherein R may be each independently a C₃ to C₄₀ substituted or unsubstituted aliphatic hydrocarbon group such as a C₃ to C₄₀ (e.g., C₅ or more and C₂₄ or less) substituted or unsubstituted alkyl group, a C₃ to C₄₀ (e.g., C₅ or more and C₂₄ or less) substituted or unsubstituted alkenyl group, a C₆ to C₄₀ (e.g., C₆ or more and C₂₀ or less) substituted or unsubstituted aromatic hydrocarbon group such as a substituted or unsubstituted C₆ to C₄₀ aryl group, or a combination thereof.

Examples of the organic ligand may include thiol compounds such as methane thiol, ethane thiol, propane thiol, butane thiol, pentane thiol, hexane thiol, octane thiol, dodecane thiol, hexadecane thiol, octadecane thiol, benzyl thiol, and the like; amines such as methanamine, ethanamine, propanamine, butanamine, pentylamine, hexylamine, octylamine, nonylamine, decylamine, dodecylamine, hexadecylamine, octadecylamine, dimethylamine, diethylamine, dipropylamine, tributyl amine, trioctyl amine, and the like; carboxylic acid compounds such as methanic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, and the like; phosphine compounds such as methyl phosphine, ethyl phosphine, propyl phosphine, butyl phosphine, pentyl phosphine, octyl phosphine, dioctyl phosphine, tributyl phosphine, trioctyl phosphine, and the like; phosphine compounds or oxide compounds thereof such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, and the like; C₅ to C₂₀ alkyl phosphinic acids such as hexylphosphinic acid, octylphosphinic acid, dodecanephosphinic acid, tetradecanephosphinic acid, hexadecanephosphinic acid, octadecanephosphinic acid, and the like; C₅ to C₂₀ alkyl phosphonic acids; and the like, but are not limited thereto. The quantum dot may include a hydrophobic organic ligand alone or in a mixture of one or more thereof. The hydrophobic organic ligand may not include a photopolymerizable moiety (e.g., an acrylate group, a methacrylate group, etc.).

Referring to FIG. 1, the color conversion layer is not positioned in a portion corresponding to the blue light emitting area BLA in the space partitioned by the bank 320. Instead, the transmission layer 330B may be positioned in the portion corresponding to the blue light emitting area BLA in the space partitioned by the bank 320.

The transmission layer 330B may include scatterers (e.g., light scatterers). The scatterers may be one or more selected from the group consisting of SiO₂, BaSO₄, Al₂O₃, ZnO, ZrO₂ and TiO₂. The transmission layer 330B may include a polymer resin and scatterers included in the polymer resin. For example, the transmission layer 330B may include TiO₂, but is not limited thereto. The transmission layer 330B may transmit light incident from the display panel.

The red color conversion layer 330R and the green color conversion layer 330G may also include scatterers. The scatterers may be one or more selected from the group consisting of SiO₂, BaSO₄, Al₂O₃, ZnO, ZrO₂ and TiO₂. As described above, the scatterers included in the red color conversion layer 330R and the green color conversion layer 330G scatter the color-converted light to increase light efficiency.

In some embodiments, in the display device including the color conversion layers, the light efficiency of the color conversion layers greatly affects the efficiency of the display device. In this case, the concentration of inorganic materials such as quantum dots and scatterers included in the color conversion layer affects the light efficiency of the color conversion layer, and as the densities of the quantum dots and the scatterers are increased, the light efficiency is improved. The display device and the manufacturing method thereof according to example embodiments include non-reactive monomers in an ink for forming the color conversion layer to increase the densities of the quantum dots and the scatterers in the color conversion layer through a process of volatilizing the non-reactive monomers and to improve the efficiency of the display device.

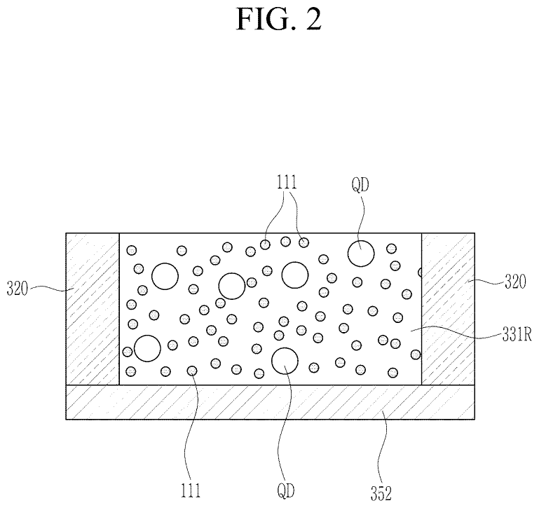

Next, hereinafter, the manufacturing method of the display device according to example embodiments will be described based on a process of forming the color conversion layers. FIGS. 2 to 5 are cross-sectional views illustrating a manufacturing process of a red color conversion layer of FIG. 1, which illustrates a portion indicated by B in the display device of FIG. 1. FIGS. 2 to 5 have illustrated the red color conversion layer 330R as an example, but the following description is equally applied even to a case of the green color conversion layer 330G.

Referring to FIG. 2, first, a color conversion layer inkjet composition 331R including quantum dots QD and scatterers 111 is injected into a light emitting area between the banks 320. The color conversion layer inkjet composition 331R may include inorganic materials, reactive monomers, additives, and/or non-reactive monomers. The inorganic materials are the quantum dots QD and the scatterers 111. The description of example materials of the quantum dots QD and the scatterers 111 is the same as that described above, and thus, will not be repeated here. In this case, in the color conversion layer inkjet composition 331R, the content of the inorganic materials including the quantum dots QD and the scatterers 111 may be up to 60 wt % (e.g., based on 100 wt % of the color conversion layer inkjet composition 331R). As the content of the inorganic materials increases, the light efficiency of the color conversion layer increases, but because the viscosity increases when the content of the inorganic materials increases, the process is not easy. Therefore, when the content of the inorganic materials exceeds 60 wt %, the inkjet jetting process may be impossible, which is not preferable.

A solvent may be included in the color conversion layer inkjet composition 331R in order to suppress or reduce an increase in the viscosity of the inkjet composition. However, in this case, there is a problem in that the inorganic materials are agglomerated and adsorbed in nozzles due to volatilization of the solvent and monomers in the inkjet nozzles. Therefore, there may be a problem of increasing mis-ejecting during inkjet jetting and clogging of the nozzle.

Accordingly, the color conversion layer inkjet composition 331R according to example embodiments does not include the solvent but includes non-reactive monomers. Because these non-reactive monomers are volatilized in a post-bake process after curing of the color conversion layer, it is possible to increase the density of the inorganic materials in the formed color conversion layer and improve light emission efficiency.

In some embodiments, the color conversion layer inkjet composition 331R according to example embodiments may include quantum dots QD, scatterers 111, base monomers, and/or non-reactive monomers. Because the description of the quantum dots QD and the scatterers 111 is the same as that described above, a detailed description of the same components will not be repeated here.

In the present specification, the non-reactive monomer may be a monomer from which a reactive group (e.g., an acrylate and/or a methacrylate) is removed from the base monomer. For example, in example embodiments, the base monomer may be hexamethylene diacrylate. In some embodiments, the base monomer may include a compound represented by Chemical Formula 1 below.

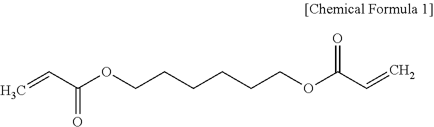 [SMILES: C=CC(=O)OCCCCCCOC(=O)C=C]

In this case, the non-reactive monomer may have a structure in which a reactive group (e.g., an acrylate group and/or a methacrylate group) is removed from Chemical Formula 1 above. For example, the non-reactive monomer may include a compound represented by Chemical Formula 2.

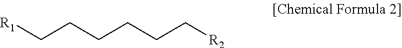

In Chemical Formula 2, R1 and R2 are compounds that are not acrylate or diacrylate (e.g., compounds that do not include an acrylate group and/or a methacrylate group). In some embodiments, R1 and R2 are non-reactive. For example, R1 and R2 may be carbons (e.g., may be aliphatic groups).

In the present specification, the non-reactive monomer means a monomer in which a crosslinking reaction does not occur in a polymerization process without including a reactive group. In this case, the content of the non-reactive monomers may be 0.1 wt % to 95 wt % of the content of the reactive monomers (e.g., based on 100 wt % of the reactive monomers).

The base monomer is a monomer in which a crosslinking reaction occurs in a polymerization process by including a reactive group. When the base monomer is hydrophilic, the non-reactive monomer may also be hydrophilic. When the base monomer is hydrophobic, the non-reactive monomer may also be hydrophobic.

Hereinabove, the configuration in which the base monomer is hexamethylene diacrylate has been described but is only an example and the present disclosure is not limited thereto.

In the color conversion layer inkjet composition 331R according to example embodiments, the sum of the contents of the reactive monomers and the non-reactive monomers may be 30 wt % to 50 wt % (e.g., based on 100 wt % of the color conversion layer inkjet composition 331R). For example, the sum may be 35 wt %.

The color conversion layer inkjet composition 331R according to example embodiments may further include various suitable additives. The content of the additives may be 1 wt % to 10 wt % (e.g., based on 100 wt % of the color conversion layer inkjet composition 331R). For example, the content may be 5 wt %, and the additives will be further described below.

The additives may be a curing agent, a dispersing agent, and/or a coupling agent.

The color conversion layer inkjet composition 331R according to example embodiments may further include a thermosetting agent and/or a photocuring agent. The curing agent included in this case may be one or more of TPO, quantacure BMS, oximes, and ethyl phenyl(2,4,6-trimethylbenzoyl)phosphinate. For example, the color conversion layer inkjet composition 331R according to example embodiments may include one or more compounds selected from the group consisting of Chemical Formulas 3 to 6 below.

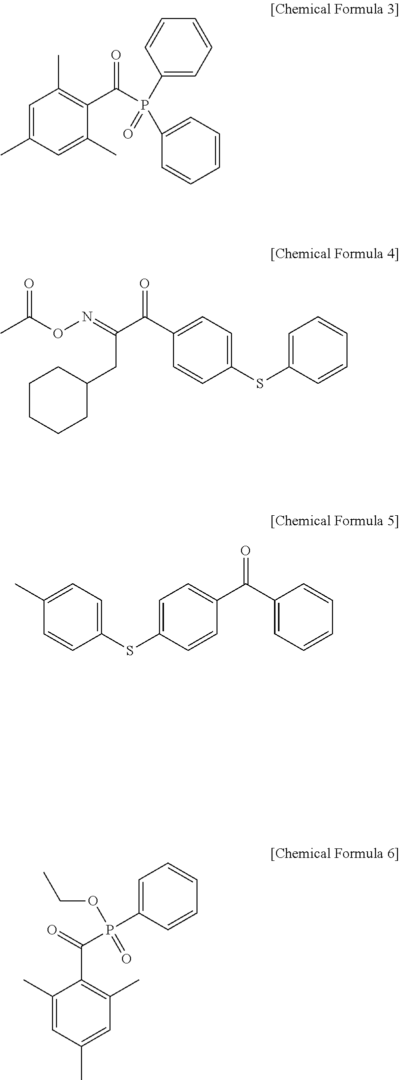 [SMILES: Cc1cc(C)c(C(=O)P(=O)(c2ccccc2)c2ccccc2)c(C)c1 ; CC(=O)O/N=C(\CC1CCCCC1)C(=O)c1ccc(Sc2ccccc2)cc1 ; Cc1ccc(Sc2ccc(C(=O)c3ccccc3)cc2)cc1 ; CCOP(=O)(C(=O)c1c(C)cc(C)cc1C)c1ccccc1]

In this case, the content of the curing agent may be 0.1 wt % to 10 wt % in the color conversion layer inkjet composition 331R (e.g., based on 100 wt % of the color conversion layer inkjet composition 331R).

In addition, the color conversion layer inkjet composition 331R according to example embodiments may further include a polyacrylate, polyurethane, and/or polyethylene-based dispersing agent. In this case, the content of the dispersing agent may be 0.1 wt % to 10 wt % (e.g., based on 100 wt % of the color conversion layer inkjet composition 331R).

The dispersing agent included in example embodiments may be one or more compounds selected from the group consisting of Chemical Formulas 7 to 9 below.

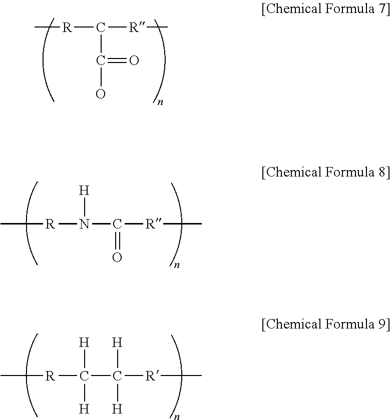

In Chemical Formulas 7 to 9, R and R′ may be amines and/or amine acids.

In addition, the color conversion layer inkjet composition 331R according to example embodiments may further include a coupling agent. In this case, the coupling agent may be one or more of acrylate, amine, and epoxy. The content of the coupling agent may be 0.1 wt % to 10 wt % in the color conversion layer inkjet composition 331R (e.g., based on 100 wt % of the color conversion layer inkjet composition 331R).

The vapor pressure of the color conversion layer inkjet composition 331R according to example embodiments having such a composition may be 10⁻⁶ mmHg to 10⁻¹ mmHg. In addition, the surface energy of the color conversion layer inkjet composition 331R may be 1 dyne/cm to 40 dyne/cm, and the viscosity may be 1 cps to cps.

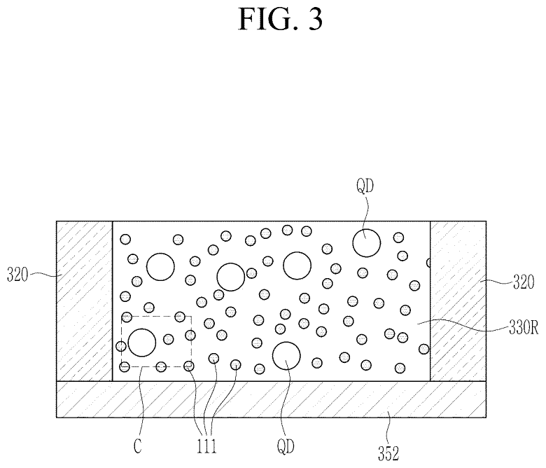

Next, referring to FIG. 3, the color conversion layer 330R is formed by curing the color conversion layer inkjet composition 331R. In this curing process, the color conversion layer 330R is formed while the base monomers react. However, the non-reactive monomers are unreacted in the curing process and then left without including a reactive group.

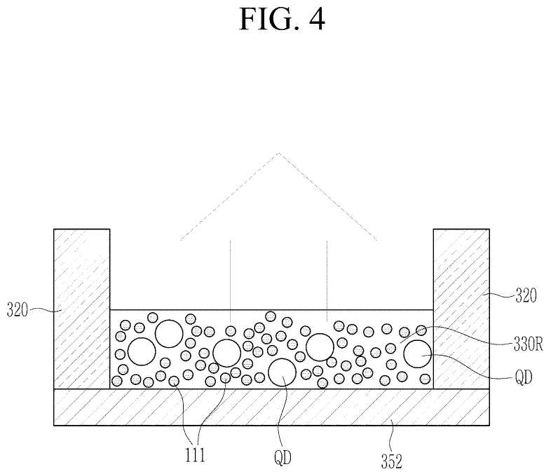

Next, referring to FIG. 4, the non-reactive monomers are volatilized through a post-bake process. The entire thickness of the color conversion layer 330R is reduced by the volatilization of the non-reactive monomers. At this time, because the quantum dots QD and the scatterers 111 included in the color conversion layer 330R are not volatilized, the densities of the quantum dots QD and the scatterers 111 per unit area increase.

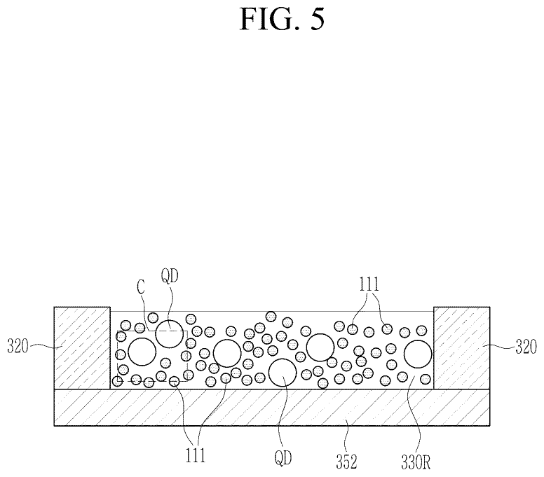

Next, referring to FIG. 5, the bank 320 is removed according to the thickness of the color conversion layer 330R. The height of the bank 320 initially formed may be um or less, and up to 90% of the bank 320 may be removed in the removal step (e.g., the height of the bank 320 may be reduced by up to 90% by the removal step). Accordingly, the height of the bank 320 may be formed to be 2 um or less. For example, the height of the bank 320 remaining after the removal step may be 1 um to um. When the bank 320 is removed according to the reduced thickness of the color conversion layer 330R, the light emission efficiency may be increased compared to before the removing of the bank 320. This is because the bank 320 protruding above the color conversion layer 330R may interfere with light emission, but when the thickness of the bank 320 is similar to the thickness of the color conversion layer 330R, the bank 320 does not (or substantially does not) interfere with light emission.

In FIGS. 3 and 5, the densities of the quantum dots QD and the scatterers 111 per unit area were compared. FIG. 3 illustrates before volatilization of the non-reactive monomers, and FIG. 5 illustrates after volatilization of the non-reactive monomers. In FIGS. 3 and 5, the same area was indicated by C, respectively. In FIGS. 3 and 5, when comparing C, it was confirmed that the numbers of the quantum dots QD and the scatterers 111 per unit area were larger in FIG. 5 than in FIG. 3. In some embodiments, as the thickness of the color conversion layer 330R decreases due to volatilization of the non-reactive monomers, the densities of the quantum dots QD and the scatterers 111 increase. Therefore, the light emission efficiency increases.

As described above, as the contents of the quantum dots QD and the scatterers 111 increase, the light emission efficiency of the display device increases. However, when the contents of the quantum dots QD and the scatterers 111 increase in the color conversion layer inkjet composition 331R, the viscosity increases, so that there is a problem that the process is difficult or impossible. In the manufacturing method of the display device according to example embodiments, the non-reactive monomers are included in the color conversion layer inkjet composition 331R and then volatilized to increase the contents of the quantum dots QD and the scatterers 111 in the color conversion layer 330R.

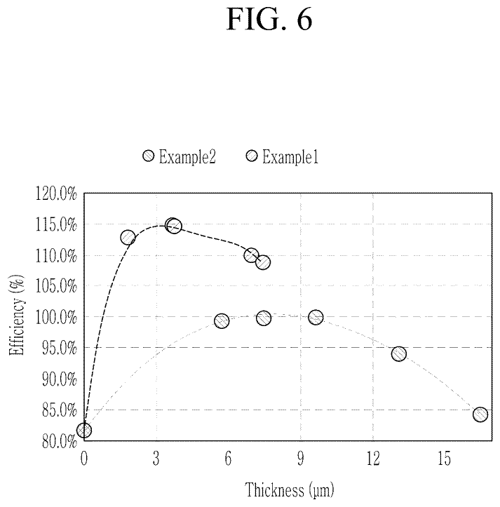

FIG. 6 is a diagram of comparing light emission efficiencies in Example 1 in which a volatilization process of non-reactive monomers is included and Example 2 in which the volatilization process of the non-reactive monomers is not included. Referring to FIG. 6, in Example 1 including the volatilization process of the non-reactive monomers, it was confirmed that the thickness of the color conversion layer was decreased, and the efficiency was increased.

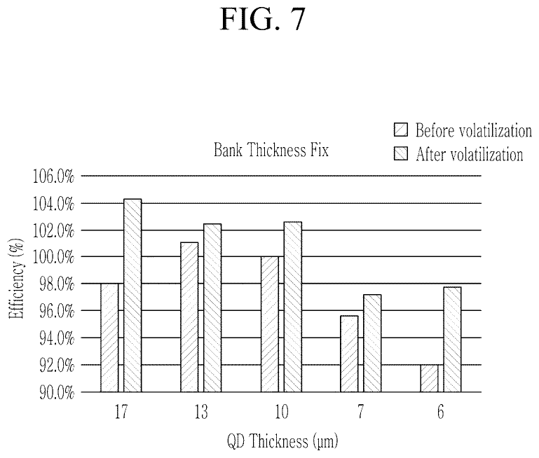

FIG. 7 is a diagram of comparing efficiencies before and after volatilization of the non-reactive monomers while varying the thickness of the color conversion layer 330R. FIG. 7 illustrates an Example in which the bank 320 is not removed. Referring to FIG. 7, it was confirmed that the efficiency after volatilization increased compared to before volatilization of the non-reactive monomers.

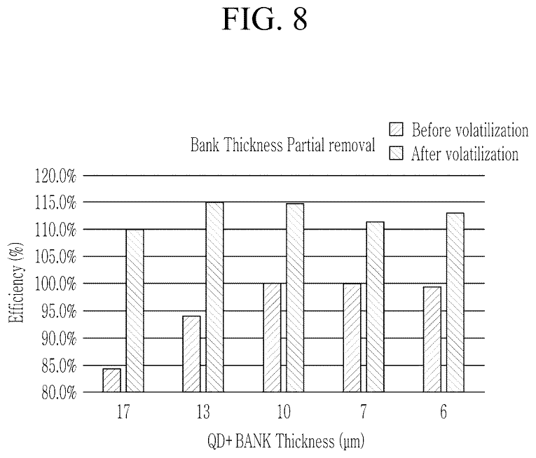

FIG. 8 is a diagram of comparing efficiencies before and after volatilization of the non-reactive monomers while varying the thickness of a color conversion layer 330R. At this time, in the case of FIG. 8, after volatilization of the non-reactive monomers, the removal process of the bank 320 was performed. Referring to FIG. 8, it was confirmed that the efficiency after volatilization was increased compared to before volatilization of the non-reactive monomers. In the case of FIG. 8 including the bank removal process, the efficiency was significantly increased compared to that of FIG. 7. As a result, it was confirmed that the efficiency was increased by the removal of the bank 320.

One feature of the manufacturing method according to example embodiments is that the volatilization process of the non-reactive monomers is performed after the color conversion layer 330R is cured. If the volatilization process of the non-reactive monomers is simultaneously performed in the curing step, a pre-bake process is required in the inkjet jetting process, and thus, the process is prolonged. In addition, because volatilization needs to occur at the same (or substantially the same) time during curing, there is a problem that the process time is increased, and a uniform surface may not be formed while the curing and volatilizing of the non-reactive monomers occur simultaneously. However, in example embodiments, because the non-reactive monomers are volatilized through the post-bake process after curing, the process time may be reduced, and a uniform (e.g., substantially uniform) surface may be obtained.

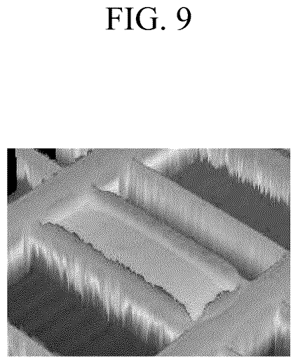

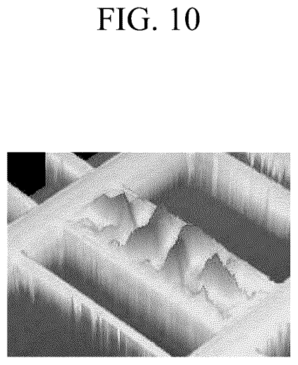

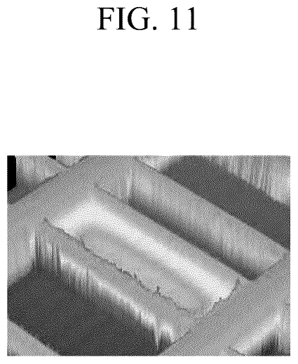

FIG. 9 is a surface image of a Comparative Example in which non-reactive monomers are volatilized after inkjet jetting, and FIG. 10 is a surface image of a Comparative Example in which non-reactive monomers are volatilized in a curing process. FIG. 11 is a surface image of an Example in which non-reactive monomers are volatilized after curing according to embodiments of the present disclosure. In the case of FIG. 9, it was confirmed that volatilization of the non-reactive monomers was not sufficiently performed. In the case of FIG. 10, the volatilized surface was not uniform. However, in the case of FIG. 11 prepared according to the Example, it was confirmed that the non-reactive monomers were sufficiently volatilized, and the surface was uniform.

Because the densities of the quantum dots and the scatterers are increased by the volatilization of the non-reactive monomers, it is also possible to lower the contents of the quantum dots and the scatterers in the inkjet composition step. In this case, the viscosity may be lowered and thus, the process may be easy. For example, because the concentration of the quantum dots and the scatterers may be increased by volatilizing the non-reactive monomers, the concentration of the quantum dots and the scatterers may be the color conversion layer inkjet composition may be reduced, thereby reducing the viscosity of the color conversion layer inkjet composition and facilitating inkjet printing of the color conversion layer inkjet composition.

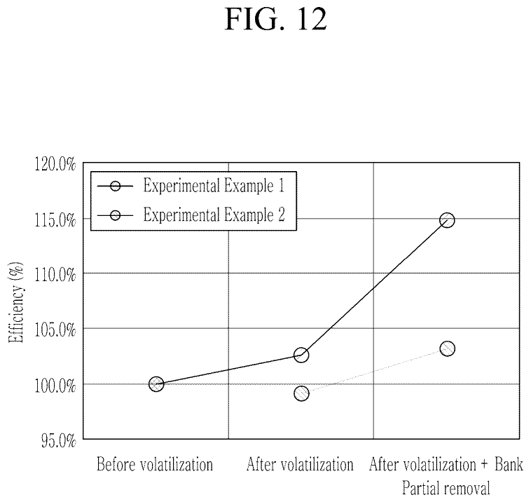

Experimental Example 1 of FIG. 12 illustrates efficiency after volatilizing non-reactive monomers and removing a bank in a state where the contents of quantum dots and scatterers are not reduced

In this case, the efficiency was increased when the non-reactive monomers were volatilized, and the efficiency was also increased when the bank was removed.

Experimental Example 2 of FIG. 12 illustrates efficiency after volatilizing non-reactive monomers and removing a bank in a state where the contents of quantum dots and scatterers are reduced. In the case of Experimental Example 2, because the contents of the quantum dots and the scatterers were reduced in the inkjet composition step, the efficiency may be lowered as compared with Experimental Example in which the contents of the quantum dots and the scatterers were not reduced after the non-reactive monomers were volatilized. However, because the efficiency increased when removing the bank, it was confirmed that the light efficiency was improved after the overall process was completed. That is, although the contents of the quantum dots and the scatterers were reduced in the inkjet composition step, it was confirmed that the efficiency was rather increased after the final preparation according to Example. This is because the densities of the quantum dots and the scatterers per unit area increased by the volatilization process of the non-reactive monomers.

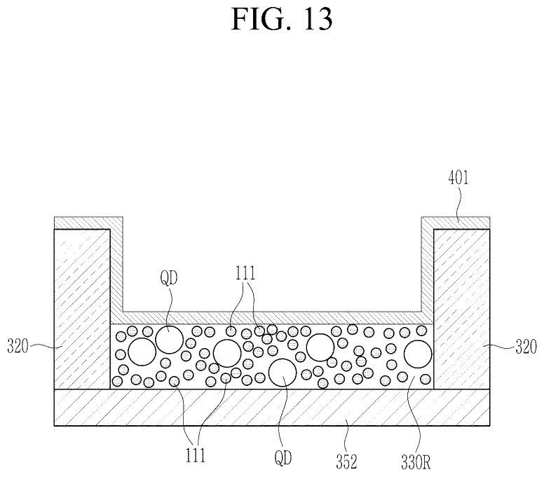

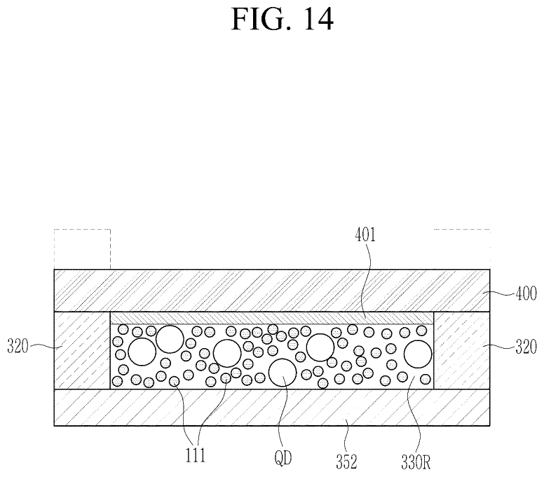

FIGS. 13 and 14 illustrate an Example in which an additional layer 401 is formed after volatilizing the non-reactive monomers. A portion of the additional layer 401 formed in this way is removed in the process of removing the bank 320. Accordingly, as illustrated in FIG. 14, the bank 320 does not overlap with the additional layer 401 and the additional layer 401 may be positioned only on the color conversion layer 330R. The first insulating layer 400 may be positioned on the additional layer 401. It can be inferred that the display device having such a structure is manufactured by the manufacturing method according to example embodiments.

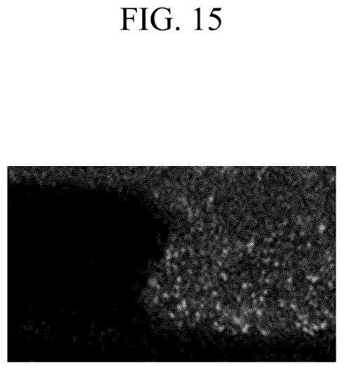

In addition, FIG. 15 is an image shown by measuring the density of quantum dots. In FIG. 15, a place where a substantial amount of quantum dots are located appears bright, and the configuration manufactured by the manufacturing method of the present disclosure may be confirmed by measuring the density of these quantum dots. In general, it is difficult that the contents of the inorganic materials including the quantum dots and the scatterers exceed 60% in the inkjet composition due to the corresponding increase in viscosity. Therefore, when the contents of the inorganic materials including the quantum dots and the scatterers exceed 60% in the formed color conversion layer, it can be inferred that the display device was manufactured by the manufacturing method according to example embodiments.

Next, hereinafter, a cross-sectional structure of the display device according to an example embodiment of the present disclosure will be described in more detail. FIG. 16 illustrates a display device according to an example embodiment. Referring to FIG. 16, a display device according to the example embodiment includes a color conversion panel 200 and a display panel 100.

Referring to FIG. 16, the color conversion panel according to example embodiments includes a second substrate 210, a color filter 230 positioned on the second substrate 210, a bank 320 positioned between the color filters 230, and a color conversion layer 330R and a transmission layer 330B positioned between the banks 320.

The color conversion panel of FIG. 16 may be positioned to overlap with a display panel.

In the color conversion panel of FIG. 16, the second substrate 210 may be positioned to face a first substrate of the display panel, and light emitted from the display panel may be emitted by passing through the second substrate 210 through the color filter 230 after passing through the color conversion layers 330R and 330G or the transmission layer 330B of the color conversion panel.

Hereinafter, a configuration of the color conversion panel according to the example embodiment of FIG. 16 will be described in more detail. The color filter 230 including a blue color filter 230B, a red color filter 230R, and a green color filter 230G is positioned on the second substrate 210.

Referring to FIG. 16, a blue dummy color filter 231B is positioned on the same layer as the blue color filter 230B. The blue color filter 230B is positioned in a blue light emitting area BLA and the blue dummy color filter 231B may be positioned in a non-light emitting area NLA overlapping with the bank 320. Although the blue color filter 230B and the blue dummy color filter 231B are illustrated as separate components in FIG. 16, the blue color filter 230B and the blue dummy color filter 231B may actually be connected to each other.

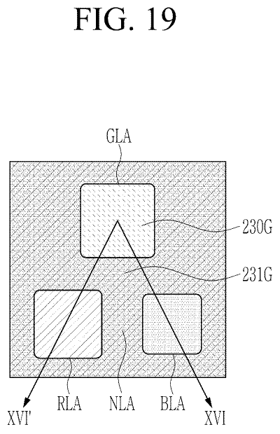

FIGS. 17 to 19 illustrate a stacking order of a blue color filter 230B, a red color filter 230R, and a green color filter 230G. A cross-section taken along line XVI-XVI′ in FIG. 19 may correspond to FIG. 16.

Referring to FIG. 17, blue color filters are positioned in the entire area except for a green light emitting area GLA and a red light emitting area RLA. Among these blue color filters, a blue color filter positioned in the blue light emitting area BLA is the blue color filter 230B, and a blue color filter positioned in the non-light emitting area NLA is the blue dummy color filter 231B. In FIG. 16, both edges of the blue color filter 230B are the non-light emitting areas NLA overlapping with the banks 320, which are the blue dummy color filters 231B.

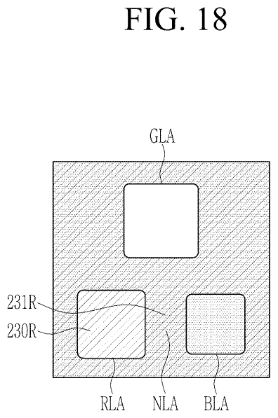

Next, referring to FIGS. 16 and 18 concurrently (e.g., simultaneously), a red color filter 230R and a red dummy color filter 231R are positioned on the blue color filter 230B and the blue dummy color filter 231B. Referring to FIG. 18, red color filters are positioned in the entire area except for the green light emitting area GLA and the blue light emitting area BLA. Among these red color filters, a red color filter positioned in the red light emitting area RLA is the red color filter 230R, and a red color filter positioned in the non-light emitting area NLA is the red dummy color filter 231R. In FIG. 16, both edges of the red color filter 230R are the non-light emitting areas NLA overlapping with the banks 320, which are the red dummy color filters 231R.

Next, referring to FIGS. 16 and 19 at the same time, a green color filter 230G and a green dummy color filter 231G are positioned on the blue color filter 230B, the blue dummy color filter 231B, the red color filter 230R, and the red dummy color filter 231R. Referring to FIG. 19, green color filters are positioned in the entire area except for the blue light emitting area BLA and the red light emitting area RLA. Among these green color filters, a green color filter positioned in the green light emitting area GLA is the green color filter 230G, and a green color filter positioned in the non-light emitting area NLA is the green dummy color filter 231G. In FIG. 16, both edges of the green color filter 230G are the non-light emitting areas NLA overlapping with the banks 320, which are the green dummy color filters 231G.

Referring to FIG. 16, the blue dummy color filter 231B, the red dummy color filter 231R, and the green dummy color filter 231G are positioned to overlap with each other in an area overlapping with the bank 320. The blue dummy color filter 231B, the red dummy color filter 231R, and the green dummy color filter 231G overlap with each other to form a color filter overlapping body A. Such a color filter overlapping body A may function in the same manner as a light blocking member. For example, the color filter overlapping body A may block light in the non-light emitting area NLA.

In this case, the blue dummy color filter 231B may be positioned closer to the second substrate 210 than the red dummy color filter 231R and the green dummy color filter 231G. A direction in which the user views an image is toward the second substrate 210, and the blue dummy color filter 231B may be positioned on a surface in which the image is viewed. This is because, compared to green or red, blue has the lowest reflectance for all light and can block (or reduce transmission of) light most effectively.

Referring to FIG. 16, a low refractive index layer 351 may be positioned on the color filter 230. The low refractive index layer 351 may have a refractive index of 1.2 or less. The low refractive index layer 351 may be a mixture of an organic material and an inorganic material.

A plurality of banks 320 is positioned on the low refractive index layer 351. The banks 320 may be spaced apart from each other with a plurality of openings therebetween, and each opening may overlap with each of the color filters 230R, 230G, and 230B in a direction vertical to the surface of the second substrate 210.

The bank 320 may include scatterers (e.g., light scatterers). The scatterers may be one or more selected from the group consisting of SiO₂, BaSO₄, Al₂O₃, ZnO, ZrO₂ and TiO₂. The bank 320 may include a polymer resin and scatterers included in the polymer resin. The content of the scatterers may be 0.1 wt % to 20 wt % (e.g., based on 100 wt % of the bank 320). For example, the content of the scatterers may be 5 wt % to 10 wt % (e.g., based on 100 wt % of the bank 320). The bank 320 including the scatterers in this range scatters the light emitted from the display panel to increase the light emission efficiency. In another example embodiment, the bank 320 may include a black material to block (or reduce transmission of) light and also prevent or reduce color mixing between neighboring light emitting areas.

A red color conversion layer 330R, a green color conversion layer 330G, a transmission layer 330B are positioned in an area between the banks 320 spaced apart from each other. In FIG. 16, the red color conversion layer 330R is positioned in an area overlapping with the red emission area RLA. The red color conversion layer 330R may convert the supplied light to red. The red color conversion layer 330R may include quantum dots. The green color conversion layer 330G may convert the supplied light to green. The green color conversion layer 330G may include quantum dots.

The transmission layer 330B may include scatterers (e.g., light scatterers). The scatterers may be one or more selected from the group consisting of SiO₂, BaSO₄, Al₂O₃, ZnO, ZrO₂ and TiO₂. The transmission layer 330B may include a polymer resin and scatterers included in the polymer resin. For example, the transmission layer 330B may include TiO₂, but is not limited thereto. The transmission layer 330B may transmit light incident from the display panel.

The red color conversion layer 330R and the green color conversion layer 330G may also include scatterers (e.g., light scatterers). The scatterers may be one or more selected from the group consisting of SiO₂, BaSO₄, Al₂O₃, ZnO, ZrO₂ and TiO₂. As described above, the scatterers included in the red color conversion layer 330R and the green color conversion layer 330G scatter the color-converted light to increase light efficiency.

The display panel 100 includes a first substrate 110, a plurality of transistors TFTs positioned on the first substrate 110, and an insulating layer 180. A first electrode 191 and a barrier 360 are positioned in the insulating layer 180, and the first electrode 191 is positioned in an opening of the barrier 360 and is connected to the transistor TFT. In some embodiments, the transistor TFT may include a semiconductor layer, a source electrode and a drain electrode connected to the semiconductor layer, and a gate electrode insulated from the semiconductor layer. A second electrode 270 is positioned on the barrier 360, and a light emitting diode layer 390 is positioned between the first electrode 191 and the second electrode 270. The first electrode 191, the second electrode 270, and the light emitting device layer 390 are collectively referred to as a light emitting diode LED. The display panel 100 may include a plurality of light emitting diodes LEDs. The plurality of light emitting diodes LEDs may emit light of different colors or may also emit light of the same color. For example, the light emitting diodes LEDs may emit light of red, green, and blue. In some embodiments, the light emitting diodes LEDs may also emit blue light and green light. The light emitting diodes LEDs may have a structure in which light emitting diodes emitting different colors are stacked. For example, the light emitting diodes LEDs may be stacked with light emitting layers emitting blue light and light emitting layers emitting green light. In some embodiments, the light emitting layers emitting blue light/green light/red light may be stacked. The barrier 360 may include a black material to prevent or reduce color mixing between adjacent light emitting diodes LEDs.

In FIG. 16, an encapsulation layer 410 may be positioned on the light emitting diodes LEDs of the display panel 100. The encapsulation layer 410 may have a multilayered structure in which organic layers and inorganic layers are alternately stacked. In the multi-layered encapsulation layer 410, a layer positioned farthest from the first substrate 110 may include SiON.

A buffer layer 420 may be positioned between the encapsulation layer 410 and the first insulating layer 400. The buffer layer 420 may bond the display panel 100 and the color conversion panel 200. The buffer layer 420 may include an organic material. A refractive index of the buffer layer 420 may be 1.6 to 1.7. Such a refractive index is a refractive index range in which the extraction efficiency of light emitted from the display panel 100 is the best.

In FIG. 16, a first insulating layer 400 positioned on the color conversion panel 200 may be included. The first insulating layer 400 is a layer for capping the red color conversion layer 330R and the transmission layer 330B. The first insulating layer 400 may include SiON. The thickness of the first insulating layer 400 may be 3500 Å to 4500 Å. The refractive index of the first insulating layer 400 may be 1.4 to 1.6. The first insulating layer 400 may include an inorganic material.

While the subject matter of this disclosure has been described in connection with what is presently considered to be practical example embodiments, it is to be understood that the present disclosure is not limited to the disclosed embodiments. On the contrary, it is intended to cover various suitable modifications and equivalent arrangements included within the spirit and scope of the appended claims, and equivalents thereof.

Description of symbols

| | |
|---|---|
| 100: Display panel | 200: Color conversion panel |
| 111: Scatterer | 330R: Red color conversion layer |
| 330G: Green color conversion layer | 330B: Transmission layer |
| 320: Bank | 360: Barrier |

What is claimed is:

1. A manufacturing method of a display device comprising:
forming banks having a plurality of openings between the banks on a substrate;
injecting a color conversion layer inkjet composition comprising non-reactive monomers into the openings between the banks;
forming a color conversion layer by curing the color conversion layer inkjet composition; and
volatilizing the non-reactive monomers by applying heat to the color conversion layer.

2. The manufacturing method of the display device of claim 1, wherein:
the color conversion layer inkjet composition comprises quantum dots, scatterers, and reactive monomers.

3. The manufacturing method of the display device of claim 1, wherein:
in the forming of the color conversion layer by curing the color conversion layer inkjet composition, the reactive monomers react.

4. The manufacturing method of the display device of claim 3, wherein:
the reactive monomer comprises hexamethylene diacrylate.

5. The manufacturing method of the display device of claim 4, wherein:
the non-reactive monomer has a structure in which diacrylate is removed from the hexamethylene diacrylate.

6. The manufacturing method of the display device of claim 2, wherein:
in the color conversion layer inkjet composition, the sum of the contents of the quantum dots and the scatterers is 60 wt % or less.

7. The manufacturing method of the display device of claim 2, wherein:
the content of the non-reactive monomers is 0.1 wt % to 95 wt % of the content of the reactive monomers.

8. The manufacturing method of the display device of claim 2, wherein:
the color conversion layer inkjet composition further comprises one or more curing agents selected from the group consisting of compounds represented by Chemical Formulas 3 to 6 below:

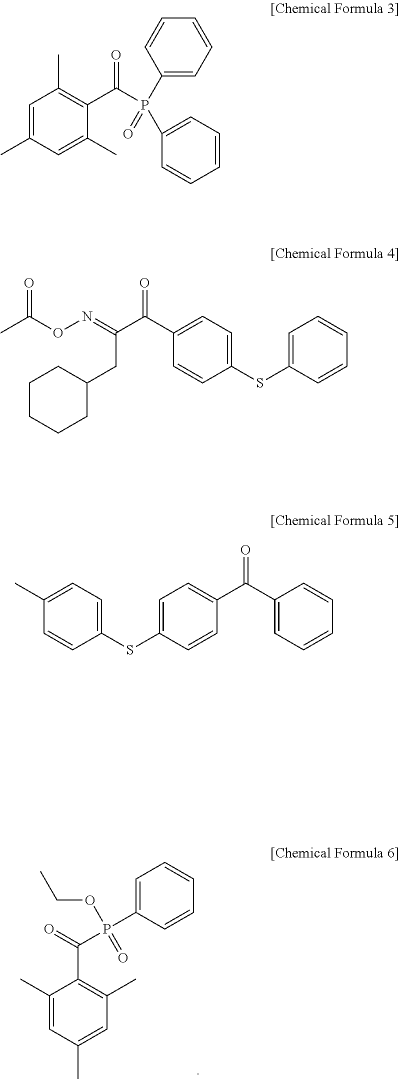 [SMILES: Cc1cc(C)c(C(=O)P(=O)(c2ccccc2)c2ccccc2)c(C)c1 ; CC(=O)O/N=C(\CC1CCCCC1)C(=O)c1ccc(Sc2ccccc2)cc1 ; Cc1ccc(Sc2ccc(C(=O)c3ccccc3)cc2)cc1 ; CCOP(=O)(C(=O)c1c(C)cc(C)cc1C)c1ccccc1]

9. The manufacturing method of the display device of claim 8, wherein:
the content of the curing agent is 0.1 wt % to 10 wt % in the color conversion layer inkjet composition.

10. The manufacturing method of the display device of claim 2, wherein:
the color conversion layer inkjet composition further comprises one or more dispersing agents selected from the group consisting of compounds of Chemical Formulas 7 to 9 below: 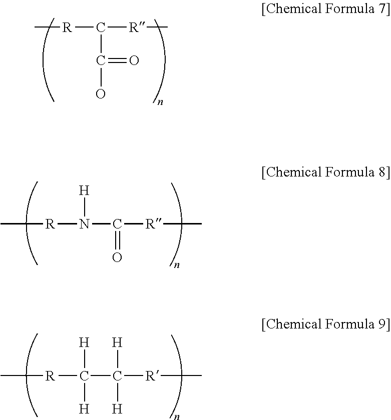
In Chemical Formulas 7 to 9, R and R′ may be amines or amine acids.

11. The manufacturing method of the display device of claim 10, wherein:
the content of the dispersing agent is 0.1 wt % to 10 wt % in the color conversion layer inkjet composition.

12. The manufacturing method of the display device of claim 1, wherein:
the vapor pressure of the color conversion layer inkjet composition is 10⁻⁶ mmHg to 10⁻¹ mmHg.

13. The manufacturing method of the display device of claim 1, wherein:
the surface energy of the color conversion layer inkjet composition is 1 dyne/cm to 40 dyne/cm.

14. The manufacturing method of the display device of claim 1, wherein:
the viscosity of the color conversion layer inkjet composition is 1 cps to 40 cps.

15. The manufacturing method of the display device of claim 1, wherein:
in the volatilizing of the non-reactive monomers by applying the heat to the color conversion layer,
the thickness of the color conversion layer is reduced.

16. The manufacturing method of the display device of claim 15, further comprising:
after the volatilizing of the non-reactive monomers by applying the heat to the color conversion layer,
removing a portion of the banks protruding above the color conversion layer.

17. The manufacturing method of the display device of claim 15, wherein:
the density of the quantum dots of the color conversion layer after the volatilizing of the non-reactive monomers by applying the heat to the color conversion layer is higher than the density of the quantum dots of the color conversion layer after the forming of the color conversion layer by curing the color conversion layer inkjet composition.

18. A display device comprising:
a color conversion panel; and
a display panel positioned to overlap with the color conversion panel,
wherein the display panel comprises:
a first substrate;
a plurality of barriers positioned on the first substrate; and
a light emitting layer positioned between adjacent ones of the barriers, and
the color conversion panel comprises:
a second substrate;
a bank positioned on the second substrate and partitioning a first light emitting area, a second light emitting area, and a third light emitting area;
color conversion layers positioned in the first light emitting area and the second light emitting area; and
an additional layer positioned on the color conversion layers,
wherein the additional layer does not overlap with the bank.

19. The display device of claim 18, wherein:
the height of the bank is 1 um to 10 um.

20. The display device of claim 18, wherein:
the color conversion layer includes quantum dots, scatterers, and non-reactive monomers.
